(19) United States
(12) Patent Application Publication
(10) Pub. No.: US 2006/0261870 A1
(43) Pub. Date: Nov. 23, 2006

(54) Clock generation circuit

(75) Inventor: Keiji Hayashida, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/411,919

(22) Filed: Apr. 27, 2006

(30) Foreign Application Priority Data
May 17, 2005 (JP) 2005-143859

(51) Int. Cl. H03L 7/06

(52) U.S. Cl. 327/158

(57) ABSTRACT

A clock generation circuit includes a phase comparator inputted with a reference clock and a feedback clock, a current controlled oscillator for generating a clock frequency according to an output of the phase comparator, a frequency dividing circuit for dividing the clock frequency by a frequency dividing rate based on a frequency dividing rate setting signal to produce a feedback clock, and a control circuit for counting the clock frequency and outputting a control current setting signal that sets a control current of the current controlled oscillator and the frequency dividing rate setting signal based on a count value.

### BACKGROUND OF THE INVENTION

1. Field of the Invention

The present invention relates to a clock generation circuit, and particularly to a frequency modulation circuit of a clock generation circuit using a Phase Locked Loop circuit (hereinafter referred to as PLL circuit).

2. Description of Related Art

As a technique to reduce EMI (Electro-Magnetic Interference) noise generated by clocks, a method to slightly modulate a frequency of an output clock from a PLL circuit before outputting it is attracting attentions in recent years. Such a clock generator is called a Spread Spectrum Clock Generator (hereinafter referred to as SSCG circuit) and inside it includes a PLL circuit and a frequency modulation circuit for modulating an output frequency from PLL circuit. A SSCG circuit lowers a peak value of unwanted radiation frequency spectrum of a clock circuit, thereby reducing EMI noise generated by a clock generation circuit.

A frequency modulation circuit used in such a SSCG circuit is disclosed by Hardin in Japanese Unexamined Patent Publication No 7-235862, for example. A circuit disclosed by Hardin adds a voltage generated by an up/down counter, a ROM, and a DA converter to a control voltage of a voltage controlled oscillator (VCO) so as to modulate a frequency outputted by VCO. Since the technique disclosed by Hardin is susceptible to variations in production tolerance, a desired modulation waveform could be difficult to obtain. As clocks are outputted using a different VCO from a VCO in a PLL circuit, variations in the VCOs is not negligible and clocks having different phases from a reference clock are outputted.

A technique disclosed by Ito in “SSCG for Harmonic Noise; Reducing EMI Suppression Component”, Nikkei Electronics, May 26, 2003, p57-62 and Japanese Unexamined Patent Publication No. 2004-104655 configures a voltage controlled oscillator (VCO) with a voltage-to-current converter (VIC) and a current controlled oscillator (ICO) and varies a current to be supplied to the ICO in order to modulate a frequency of an output clock from the ICO. With a technique disclosed by Ito, an oscillation frequency is controlled by a current, thereby reducing an influence from variations in production tolerance. However there is a conflicting operation as a PLL circuit is for synchronizing a reference clock and an output clock, whereas a frequency modulation circuit is for modulating a frequency of an output clock. The present invention has recognized that it therefore fluctuates a modulation waveform or increases an area of PLL circuit in order to extend a lock range for a PLL circuit.

As described in the foregoing, it is difficult for a conventional PLL circuit to suppress a fluctuation in modulation waveform caused by production tolerance variations. Even if such a variation in modulation waveform can be reduced, it is still difficult to obtain a desired modulation waveform.

### SUMMARY OF THE INVENTION

According to an aspect of the present invention, there is provided a clock generation circuit that includes a phase comparator inputted with a reference clock and a feedback clock, a voltage controlled oscillator for generating an operation clock according to an output of the phase comparator, a first modulation unit for counting the operation clock and changing a frequency dividing rate of the feedback clock inputted to the phase comparator based on a count value, a second modulation unit for counting the operation clock, adding a current based on a count value to a control current of the current controlled oscillator, and changing an oscillation frequency of the current controlled oscillator.

According to another aspect of the present invention, there is provided a clock generation circuit that includes a phase comparator inputted with a reference clock and a feedback clock, a voltage controlled oscillator for generating a operation clock based on an output from the phase comparator, a frequency dividing circuit for dividing the operation clock by a frequency dividing rate according to an frequency dividing rate setting signal to produce the feedback clock, and a control circuit for counting the operation clock and outputting the control current setting signal that specifies a control current of the current controlled oscillator and outputting the frequency dividing rate setting signal.

The present invention enables a clock generation circuit to modulate a frequency as desired.

### BRIEF DESCRIPTION OF THE DRAWINGS

The above and other objects, advantages and features of the present invention will be more apparent from the following description taken in conjunction with the accompanying drawings, in which:

FIG. 1 is a block diagram showing a PPL circuit according to an embodiment of the present invention;

FIG. 2 is a block diagram showing a control circuit of an embodiment of the present invention;

FIGS. 3A to 3D are views showing a relationship between an output clock of ICO, an output current of DAC, and a frequency dividing rate; and

FIG. 4 is a view showing an output frequency according to an embodiment of the present invention.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

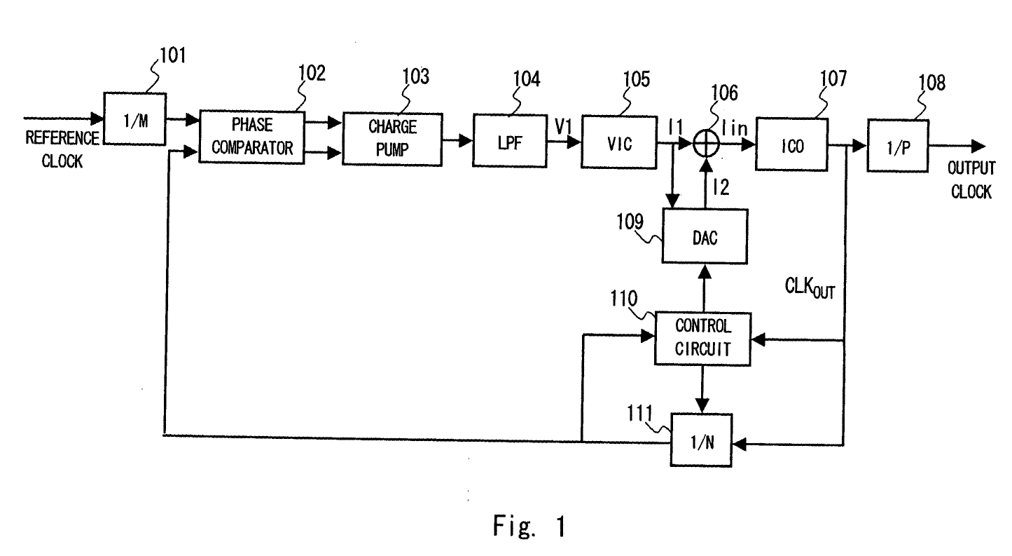

An embodiment of the present invention is described hereinafter in detail with reference to the drawings. FIG. 1 is a block diagram showing a PLL circuit having a frequency modulation circuit (clock generation circuit) according to the embodiment. The PLL circuit of this embodiment includes a first frequency dividing circuit 101, a phase comparator 102, a charge pump circuit 103, a low-pass filter (LPF) 104, a voltage-to-current converter (VIC) 105, an adder 106, a current controlled oscillator (ICO) 107, a second frequency dividing circuit 108, a digital-to-analog converter (DAC) 109, a control circuit 110, and a third frequency dividing circuit 111.

The first frequency dividing circuit 101 is a circuit for dividing an input reference clock by M (wherein M is a natural number) before outputting it. An output from the first frequency dividing circuit 101 is supplied to the phase comparator 102. The phase comparator 102 is a circuit for detecting a phase difference between an output signal from the first frequency dividing circuit and an output signal (operation clock) from the ICO 107 provided via the third frequency dividing circuit 111. The phase comparator 102 outputs a phase difference signal UP and DOWN according to the detected phase difference.

The charge pump circuit 103 is a circuit for generating and outputting a voltage corresponding to the phase difference signal UP and DOWN outputted by the phase comparator 102. The LPF 104 is a circuit for filtering the voltage outputted from the charge pump circuit 103 and outputting it as a voltage signal V1 with high frequency component being eliminated.

The VIC 105 is a circuit for converting the voltage signal V1 outputted from the LPF 104 to a current signal I1 and outputting the current signal I1. The adder 106 is a circuit for adding a current I2 outputted from the DAC 109 to the current I1 outputted from the VIC 105 to produce an output frequency control current Iin. The output frequency control current Iin is outputted to the ICO 107. The ICO 107 is a circuit for generating and outputting a operation clock CLKOUT having a frequency based on the current Iin that is outputted by the adder 106. The second frequency dividing circuit 108 is a circuit for dividing the operation clock CLKOUT outputted by the ICO by P (wherein P is a natural number) and outputting it.

The DAC 109 is a circuit for outputting a digital signal (control current setting signal) outputted from the control circuit 110 as an analog signal. The DAC 109 outputs a current having a current value based on the digital signal. Based on an output from the DAC 109, an output clock from the PLL circuit is modulated.

The control circuit 110 outputs a digital signal (control current setting signal) that is to be a modulation data to the DAC 109. The control circuit 110 is a circuit for outputting a signal for setting a frequency dividing rate to the third frequency dividing circuit 111. The control circuit 110 includes inside an up/down counter. The control circuit 110 outputs data corresponding to a count value of the up/down counter to the DAC 109 and the third frequency dividing circuit 111. The up/down counter embedded in the control circuit 110 is a counter for counting clocks CLKOUT outputted from the ICO 107 and repeating count-up and count-down operations. When the up/down counter counts up a clock outputted from the ICO 107 to an upper limit, the up/down counter switches from count-up to count-down operation. When the up/down counter counts down to a lower limit, it then switches back to a count-up operation. The control circuit 110 of this embodiment synchronizes with an output clock from the third frequency dividing circuit, and then outputs a count value of the up/down counter to the DAC 109. Further, the control circuit 110 changes a frequency dividing rate of the third frequency dividing circuit according to the count value every time the count value reaches a specified value.

The third frequency dividing circuit 111 is a circuit where a frequency dividing rate is determined according to the count value of the up/down counter outputted by the control circuit 110. The third frequency dividing circuit 111 outputs a signal outputted by the ICO 107 according to the frequency dividing rate specified by the control circuit 110.

An operation of the PLL circuit with a configuration as above is described hereinafter in detail.

In FIG. 1, the phase comparator 102 detects a phase difference between a reference clock and a clock being divided and feedback. The charge pump 103, and the LPF 104 produce a voltage signal corresponding to the phase difference. These operations are the same in a conventional PLL circuit.

In the PLL circuit of this embodiment, a voltage signal corresponding to a phase difference is converted to a current signal by the VIC 105. The current signal is supplied to the DAC 109 as a reference current.

A digital signal is inputted to the DAC 109 from the control circuit 110. The DAC 109 outputs a current for a frequency modulation based on the digital signal. The adder 106 adds a current outputted by the DAC 109 to a current outputted by the VIC 105 and outputs the added current to the ICO 107. As the ICO 107 generates a clock signal according to this current, the ICO 107 outputs a clock signal with its frequency being modulated according to an output current from the DAC 109. The clock signal is supplied to other circuit through the second frequency dividing circuit 108. The operation clock outputted by the ICO is also supplied to the up/down counter in the control circuit 110. The control circuit 110 controls the digital signal for modulation to be outputted to the DAC 109 and the frequency dividing rate of the third frequency dividing circuit according to the count value of the up/down counter.

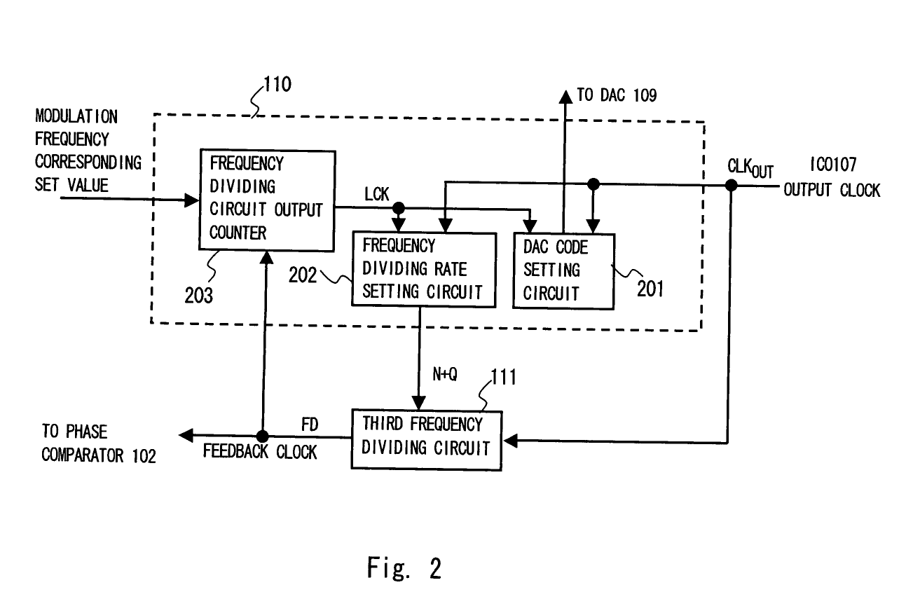

FIG. 2 is a block diagram showing a control circuit 110 of this embodiment. A control circuit of this embodiment includes a DAC code setting circuit 201, a frequency dividing rate setting circuit 202, and a frequency dividing circuit output counter 203. The DAC code setting circuit 201 is comprised of an up/down counter and such. The DAC code setting circuit 201 counts clocks outputted by the ICO 107 and outputs a code corresponding to the count value to the DAC 109. The frequency dividing rate setting circuit 202 also includes inside an up/down counter and such. The frequency dividing rate setting circuit 202 outputs a frequency dividing setting signal according to the count value of the up/down counter to the third frequency dividing circuit.

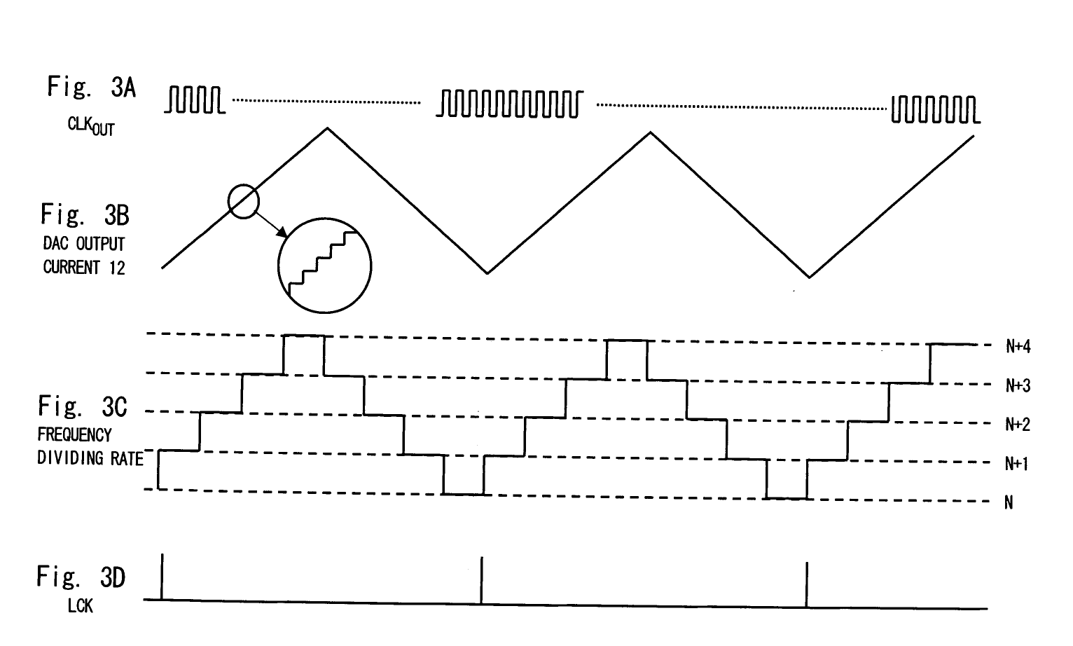

FIGS. 3A to 3D are views showing an output clock of ICO, a movement of an output current of the DAC 109 that is based on the count value of the DAC code setting circuit inside the control circuit 110, and a movement of the frequency dividing rate for the third frequency dividing circuit 111. An operation of the control circuit 110, the DAC 109, and the third frequency dividing circuit 111 are described hereinafter with reference to FIGS. 3A to 3D.

FIG. 3A shows a clock outputted by the ICO of this embodiment. In this embodiment, the DAC code setting circuit 201 inside the control circuit 110 counts the clock and repeats count-up and count-down operations. Based on the count value of the up/down counter inside the DAC code setting circuit 201, the DAC 109 generates a current for frequency modulation and outputs it. A movement of the current outputted by the DAC 109 is shown in FIG. 3B. Although FIG. 3B is illustrated in a way that the output current of the DAC 109 changes in a linear fashion, the output current actually moves in a stepped manner based on a count value, as partly enlarged in FIG. 3B. A frequency of the clock outputted by the ICO 107 changes in accordance with a current outputted by the DAC 109.

The control circuit 110 of this embodiment changes a frequency dividing rate of the third frequency dividing circuit 111 every time clocks outputted by the ICO is counted to a given number. FIG. 3C shows a movement of the frequency dividing rate. Specifically, the control circuit 110 sets the frequency dividing rate of the third frequency dividing circuit to be high (1/N having a larger denominator) when a frequency of a clock outputted by the ICO 107 is high. On the other hand, the control circuit 110 sets the frequency dividing rate to be low (1/N having a smaller denominator) when a frequency of a clock outputted by the ICO 107 is low. In FIGS. 3A to 3D, although a movement of a frequency dividing rate is set to be from N to N+4 for the ease of explanation, the setting may be changed as appropriate where the change in the frequency dividing rate shall be performed within a range of N to N+Q in a stepped manner.

Although the number of steps and a magnitude of frequency dividing rate change can be specified as desired, generally the frequency dividing rate that can be controlled by a frequency dividing circuit is not finely configured. Accordingly the number of steps is less than changes in the current of the DAC 109 based on a setting for a DAC code output. By controlling a frequency dividing rate based on the count value of output clocks from the ICO, it is possible to suppress a conflicting operation between a modulation by a frequency modulation circuit using the DAC 109 and a PLL circuit, consequently stabling changes in the frequency outputted by the ICO 107.

In this embodiment, a count value based on a modulated frequency, for example, is set to a frequency dividing circuit output counter 203. The frequency dividing circuit output counter 203 counts a feedback clock outputted by the third frequency dividing circuit and outputs a reset signal LCK by each count value according to a modulation frequency. In this embodiment, for example the number of count of the feedback clock is set to be a value that corresponds to a count-up and count-down operations by the up/down counter in the third frequency dividing circuit (See FIG. 3D).

In this embodiment, the frequency dividing circuit output counter 203 outputs a reset signal LCK to the DAC code setting circuit 201 and the frequency dividing rate setting circuit 202 every time the frequency dividing circuit output counter 203 counts a clock of a specified value. This allows a synchronization in every cycle for modulation frequency even if the number of steps for the frequency dividing rate outputted by a frequency dividing setting circuit is different from the number of steps the DAC code setting circuit outputs, enabling a stable operation.

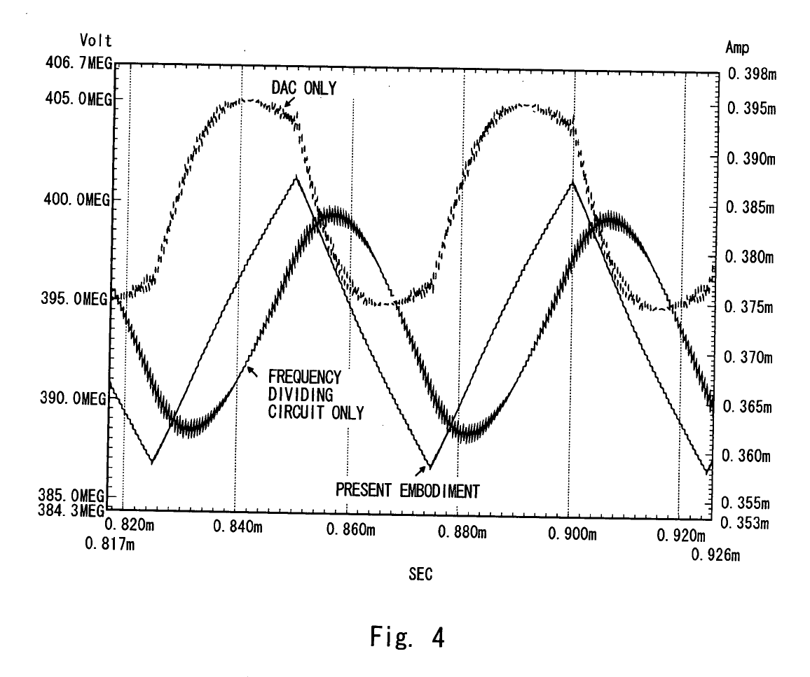

FIG. 4 shows a movement of output frequency according to this embodiment. As shown in FIG. 4, controlling only an output from the DAC 109 to modulate its frequency fluctuates a waveform, at a turning point of the frequency curve, the time movement of the frequency is saturated, causing the output frequency to change to a sine waveform. Further, without a frequency modulation by the DAC but controlling only the frequency dividing rate of a feedback frequency dividing circuit (the third frequency dividing circuit) also changes the output frequency to be a sine waveform, along with fluctuation of the frequency around a turning point of the curve. However with a clock generation circuit (PLL circuit) of this embodiment, it is possible to modulate a frequency according to an output from the up/down counter in more stabled way having nearly a triangular waveform.

As described in detail above, with the PLL circuit of this embodiment, an output current from the DAC 109 and a frequency dividing rate of the third frequency dividing circuit changes according to a operation clock outputted by the ICO 107. Controlling in this manner enables to modulate a frequency for an output of the PLL circuit as desired. Conventionally, in an attempt to modulate an output frequency to form a triangular waveform, even when changing only a DAC code for the DAC 109 to be a triangular waveform as shown in FIG. 4, an output sometimes is modulated to be a sine waveform. However in this embodiment, changing the output current from the DAC 109 and the frequency dividing rate of the third frequency dividing circuit allows to modulate a frequency in triangular waveform, or other waveform, as desired. Further, resetting the DAC code setting circuit 201 and the frequency dividing rate setting circuit 202 according to a cycle of a modulation frequency prevents a gap created due to a difference in the number of steps to operate in synchronization. Further in this embodiment, the frequency dividing rate of the third frequency dividing circuit t be changed every time the ICO outputs a clock of a specified number, however if the number of steps the frequency dividing circuit 111 varies is less than the number of steps the DAC 109 varies, it may be configured in a way that the frequency dividing rate to be changed every time a feedback clock that is outputted by the third frequency dividing circuit is counted to a specified number.

It is apparent that the present invention is not limited to the above embodiment and it may be modified and changed without departing from the scope and spirit of the invention.

What is claimed is:

1. A clock generation circuit comprising:
a phase comparator inputted with a reference clock and a feedback clock;
a current controlled oscillator for generating an operation clock according to an output of the phase comparator;
a first modulation unit for counting the operation clock and changing a frequency dividing rate of the feedback clock inputted to the phase comparator according to a count value; and
a second modulation unit for counting the operation clock and for changing a control current of the current controlled oscillator according to a count value.

2. A clock generation circuit comprising:
a phase comparator inputted with a reference clock and a feedback clock;
a current controlled oscillator for generating an operation clock based on an output from the phase comparator;
a frequency dividing circuit for dividing the operation clock by a frequency dividing rate based on a frequency dividing rate setting signal to produce the feedback clock; and
a control circuit for counting the operation clock and outputting a control current setting signal that sets a control current of the current controlled oscillator and the frequency dividing rate setting signal based on a count value.

3. The clock generation circuit according to claim 2, wherein the control circuit comprising:
a first setting circuit for counting the operation clock and outputting the control current setting signal; and
a frequency dividing rate setting circuit for counting the operation clock and outputting the control frequency dividing rate setting signal.

4. The clock generation circuit according to claim 2, further comprising a D/A converter for generating a current having a current value based on the control current setting signal.

5. The clock generation circuit according to claim 3, wherein the control circuit counts the feedback clock, and further includes a counter for outputting a reset signal to the first setting circuit and a frequency rate setting circuit based on a count value.

6. The clock generation circuit according to claim 5, wherein the count value for the counter to output a reset signal is determined according to a cycle that changes a control current of the current controlled oscillator.
